(19) United States
(12) Patent Application Publication
(10) Pub. No.: US 2024/0076541 A1
(43) Pub. Date: Mar. 7, 2024

(54) RESIN COMPOSITION AND LIGHT-EMITTING DEVICE

(71) Applicant: NICHIA CORPORATION, Anan-shi (JP)

(72) Inventor: Hyogo YAGI, Itano-gun (JP)

(73) Assignee: NICHIA CORPORATION, Anan-shi (JP)

(21) Appl. No.: 18/230,731

(22) Filed: Aug. 7, 2023

(30) Foreign Application Priority Data
Sep. 2, 2022 (JP) 2022-140215

(51) Int. Cl. C09K 11/02; C08K 3/34; C08K 5/17; C08K 5/5317; C09K 11/61; H01L 33/50; H01L 33/56

(52) U.S. Cl. CPC C09K 11/02; C08K 3/34; C08K 5/175; C08K 5/5317; C09K 11/617; H01L 33/502; H01L 33/507; H01L 33/56

(57) ABSTRACT

A resin composition includes a silicone resin, a Mn-activated fluoride phosphor, and a chelating agent. The chelating agent may include, for example, at least one selected from the group consisting of an aminocarboxylic-acid-based chelating agent and a phosphonic-acid-based chelating agent. The light-emitting device is provided with, for example, a substrate, a light-emitting element disposed on the substrate, and a wavelength conversion member covering the light-emitting element. The wavelength conversion member of the light-emitting device includes a cured product of a silicone resin, a Mn-activated fluoride phosphor, and a chelating agent.

### CROSS-REFERENCE TO RELATED APPLICATIONS

The present application claims priority under 35 U.S.C. § 119 to Japanese Patent Application No. 2022-140215, filed Sep. 2, 2022, the contents of which are hereby incorporated by reference in their entirety.

### BACKGROUND

### 1. Technical Field

The present disclosure relates to a resin composition and a light-emitting device.

### 2. Description of Related Art

Light-emitting devices in which a light-emitting element and a phosphor are combined are utilized in a wide range of fields, such as in illumination, on-board lighting, displays, and liquid crystal backlights, for example. For example, a phosphor used in a light-emitting device for a backlight for a liquid crystal display device has been required to have a narrow half-value width of an emission peak and a high color purity. Japanese Patent Publication No. 2014-141684 discloses a red phosphor which is a Mn-activated complex fluoride having a specific composition, and proposes a surface treatment method for improving the moisture resistance the red phosphor.

### SUMMARY

An object of an aspect of the present disclosure is to provide a resin composition that can improve reliability in a light-emitting device containing a Mn-activated fluoride phosphor, and a light-emitting device using the resin composition.

According to an aspect of the present disclosure, a resin composition includes a silicone resin, a Mn-activated fluoride phosphor, and a chelating agent.

According to an aspect of the present disclosure, a light-emitting device includes: a substrate; a light-emitting element disposed on the substrate; and a wavelength conversion member covering the light-emitting element. The wavelength conversion member of the light-emitting device includes a cured product of a silicone resin, a Mn-activated fluoride phosphor, and a chelating agent.

According to an aspect of the present disclosure, a resin composition can be provided that enables improvement of reliability in a light-emitting device including a Mn-activated fluoride phosphor, and a light-emitting device using the resin composition.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a schematic cross-sectional view illustrating an example of a light-emitting device according to the present disclosure.

### DETAILED DESCRIPTION

The word “step” herein includes not only an independent step, but also a step that cannot be clearly distinguished from another step provided that the anticipated purpose of the step is achieved. If a plurality of substances applicable to each component in a composition are present, the content of each component in the composition means a total amount of the plurality of substances present in the composition, unless otherwise specified. Furthermore, with respect to an upper limit and a lower limit of numerical ranges described herein, the numerical values exemplified as the numerical range can be freely selected and combined. In the present specification, a plurality of elements separated by commas (,) in a formula representing the composition of the phosphor or the light-emitting material means that at least one element among the plurality of elements is contained in the composition. In a formula representing the composition of the phosphor, characters preceding the colon (:) represent a host crystal, and characters following the colon (:) represent an activating element. Note that herein, relationships such as the relationship between a color name and a chromaticity coordinate, and the relationship between a wavelength range of light and a color name of monochromatic light are in accordance with JIS Z 8110. The full width at half maximum of a phosphor means a wavelength width (full width at half maximum: FWHM) of an emission spectrum at which the emission intensity becomes 50% of the maximum emission intensity in the emission spectrum of the phosphor. An embodiment of the present invention will be described below with reference to the accompanying drawings. The embodiments presented below exemplify the resin compositions and light-emitting devices using thereof that embody the technical concept of the present invention, but the present invention is not limited to the resin compositions and light-emitting devices presented below.

Resin Composition

The resin composition includes a silicone resin, a Mn-activated fluoride phosphor, and a chelating agent. When the resin composition contains the chelating agent, in the light-emitting device including the wavelength conversion member formed by curing the resin composition, a decrease in luminous flux of the light-emitting device due to a temporal change of the Mn-activated fluoride phosphor is reduced, and reliability of the light-emitting device is improved. It is conceivable that this is because, for example, the chelating agent captures Mn ions generated from the Mn-activated fluoride phosphor due to moisture absorption of the wavelength conversion member to reduce generation of oxides containing manganese from the Mn ions.

The silicone resin is a resin having a siloxane structure in the molecule, and may be a curable silicone resin. Examples of the curable silicone resin include an addition curable silicone resin, a condensation curable silicone resin, and an ultraviolet or electron beam curable silicone resin. An example of the addition-curable silicone resin includes a silicone resin in which curing is achieved by reacting an organopolysiloxane having an unsaturated hydrocarbon group introduced into a terminal or a side chain of the organopolysiloxane with an organohydrogensiloxane using a platinum catalyst. An example of the condensation curable silicone resin includes a silicone resin having a three dimensional crosslinked structure formed by a condensation reaction between an organopolysiloxane having a hydroxy group at a terminal of the organopolysiloxane and an organopolysiloxane having a silicon-hydrogen bond at a terminal of the organopolysiloxane using an organotin catalyst. Examples of the ultraviolet-curable silicone resin include a silicone resin utilizing the same radical reaction as that of normal silicone rubber crosslinking, a silicone resin which is photocured by introducing an unsaturated group, a silicone resin which is crosslinked by a strong acid generated from an initiator by introducing an epoxy group, and a silicone resin which is crosslinked by an addition reaction of thiol to vinyl siloxane. In addition, an electron beam can be used instead of the ultraviolet ray. The electron beam has higher energy than the ultraviolet ray, and it is possible to carry out a crosslinking reaction by a radical without using an initiator as in the case of ultraviolet curing.

Examples of the silicone resin include a phenyl silicone resin, a diphenyl silicone resin, an alkyl silicone resin, a dialkyl silicone resin, and an alkylphenyl silicone resin. The silicone resin may be a modified silicone resin such as an epoxy-modified silicone resin. The silicone resin may preferably include a phenyl silicone resin. The silicone resin can be appropriately selected from available silicone resins and can be contained in the resin composition.

In one aspect, the silicone resin may be an addition-curable silicone resin, and may contain organopolysiloxane containing a crosslinkable functional group and an aryl group per molecule, organohydrogenpolysiloxane containing at least two silicon atoms to which a hydrogen atom is bonded (SiH groups) per molecule, and a hydrosilylation catalyst.

The organopolysiloxane contains at least two crosslinkable functional groups per molecule, preferably in a range from 2 to 100, more preferably in a range from 2 to 50 of crosslinkable functional groups per molecule. The crosslinkable functional group contained in the organopolysiloxane is preferably an aliphatic unsaturated hydrocarbon group bonded to a silicon atom. The aliphatic unsaturated hydrocarbon group may be, for example, a monovalent aliphatic hydrocarbon group having an unsaturated bond and having 2 to 8 carbon atoms, preferably an alkenyl group having 2 to 8 carbon atoms. Examples of the alkenyl group bonded to a silicon atom include a vinyl group, an allyl group, a propenyl group, an isopropenyl group, a butenyl group, a hexenyl group, a cyclohexenyl group, and an octenyl group. The crosslinkable functional group may preferably be vinyl groups. The aliphatic unsaturated hydrocarbon group may be bonded to either a silicon atom at the end of the molecular chain of the organopolysiloxane or a silicon atom in the middle of the molecular chain, or may be bonded to both of them.

Examples of the aryl group contained in the organopolysiloxane include a phenyl group, a tolyl group, a xylyl group, and a naphthyl group, and preferably a phenyl group. In the organopolysiloxane, the aryl group content of the substituents bonded to silicon atoms (excluding oxygen atoms forming siloxane bonds) may be, for example, 5 mol % or more, preferably in a range from 10 mol % to 80 mol %, or in a range from 20 mol % to 70 mol %.

The organic group bonded to a silicon atom other than the crosslinkable functional group and the aryl group contained in the organopolysiloxane may be, for example, an unsubstituted or substituted monovalent hydrocarbon group having 1 to 18 carbon atoms, preferably 1 to 10 carbon atoms or 1 to 8 carbon atoms. Examples of the monovalent hydrocarbon group include alkyl groups such as a methyl group, an ethyl group, a propyl group, an isopropyl group, a butyl group, an isobutyl group, a tert-butyl group, a pentyl group, a neopentyl group, a hexyl group, a cyclohexyl group, an octyl group, a nonyl group, and a decyl group; aralkyl groups such as a benzyl group, a phenylethyl group, and a phenylpropyl group; or groups formed by substituting a part or all of hydrogen atoms of these groups with a halogen atom such as fluorine, bromine, or chlorine, a cyano group, or the like, and examples thereof include a chloromethyl group, a chloropropyl group, a bromoethyl group, a trifluoropropyl group, and a cyanoethyl group. The organic group bonded to the silicon atom other than the crosslinkable functional group and the aryl group may be a methyl group.

The molecular structure of the organopolysiloxane may be any structure that can cause crosslinking reaction, and examples thereof include a linear structure, a branched structure, a linear structure having a partially branched or cyclic structure, and the like. The organopolysiloxane can be used alone or in combination of two or more kinds thereof. For example, the organopolysiloxane may contain a linear silicone oil and a silicone resin having a branched structure.

The organohydrogenpolysiloxane may contain at least two (usually in a range from 2 to 300) silicon atoms to which hydrogen atoms are bonded (SiH groups) per molecule, and preferably 3 or more, in a range from 3 to 200, in a range from 3 to 100, or in a range from 3 to 20. Any organohydrogenpolysiloxane may be used as long as the SiH group in the molecule undergoes an addition reaction with the aliphatic unsaturated hydrocarbon group of the functional group contained in the organopolysiloxane in the presence of a hydrosilylation catalyst to form a crosslinked structure.

The organohydrogenpolysiloxane has an organic group bonded to a silicon atom. Examples of the organic group bonded to a silicon atom include monovalent hydrocarbon groups other than aliphatic unsaturated hydrocarbon groups. The organic group bonded to a silicon atom may be, for example, an unsubstituted or substituted monovalent hydrocarbon group having 1 to 12 carbon atoms, and preferably 1 to 10 carbon atoms. Examples of the organic group bonded to a silicon atom include: alkyl groups such as a methyl group, an ethyl group, a propyl group, a butyl group, a hexyl group, and a dodecyl group; aryl groups such as a phenyl group; aralkyl groups such as a 2-phenylethyl group and a 2-phenylpropyl group; and groups formed by substituting a part or all of hydrogen atoms of these groups with a halogen atom such as fluorine, bromine and chlorine, a cyano group, and the like, and examples thereof include a chloromethyl group, a chloropropyl group, a bromoethyl group, a trifluoropropyl group, a cyanoethyl group; and epoxy group-containing organic groups (glycidyl group or glycidyloxy group-substituted alkyl group) such as a 2-glycidoxyethyl group, a 3-glycidoxypropyl group, and a 4-glycidoxybutyl group. The organic group bonded to the silicon atom of the organohydrogenpolysiloxane preferably contains at least an aryl group. The organohydrogenpolysiloxane may have aryl groups, particularly phenyl groups, in a range from 5 mol % to 70 mol % of the substituents bonded to silicon atoms (excluding oxygen atoms forming siloxane bonds).

Examples of the molecular structure of the organohydrogenpolysiloxane include linear, branched, cyclic, and linear structures having a partially branched or cyclic structure. Specific examples of the organohydrogenpolysiloxane include tris(dimethylhydrogensiloxy) methylsilane, tris(dimethylhydrogensiloxy) phenylsilane, 1,1,3,3-tetramethyldisiloxane, 1,3,5,7-tetramethylcyclotetrasiloxane, a methylhydrogenpolysiloxane capped at both terminals with trimethylsiloxy groups, a dimethylsiloxane-methylhydrogensiloxane copolymer capped at both terminals with trimethylsiloxy groups, a dimethylpolysiloxane capped at both terminals with dimethylhydrogensiloxy groups, a dimethyl siloxane-methylhydrogensiloxane copolymer capped at both terminals with dimethylhydrogensiloxy groups, a methylhydrogensiloxane-diphenyl siloxane copolymer capped at both terminals with trimethylsiloxy groups, a methylhydrogensiloxane-diphenylsiloxane-dimethylsiloxane copolymer capped at both terminals with trimethylsiloxy groups, a copolymer consisting of (CH₃)₂HSiO_{1/2} units and SiO_{4/2} units, and a copolymer consisting of (CH₃)₂HSiO_{1/2} units, SiO_{4/2} units, and (C₆H₅) SiO_{3/2} units.

A blending amount of the organohydrogenpolysiloxane may be an amount such that the number of SiH groups relative to a total number of crosslinkable functional group in the organopolysiloxane, preferably aliphatic unsaturated hydrocarbon groups, is in a range from 0.5 to 5, preferably in a range from 0.8 to 3, or in a range from 1 to 2.5. When the organohydrogenpolysiloxane is contained in such an amount that the number of the SiH group of the organohydrogenpolysiloxane relative to the crosslinkable functional group in the organopolysiloxane falls within the above range, it is possible to reduce the possibility that the addition reaction unintentionally proceeds, the crosslinked structure becomes non-uniform, and the storage stability of the composition deteriorates.

Examples of the hydrosilylation catalyst include platinum-based, palladium-based, and rhodium-based catalysts. Examples of the platinum-based hydrosilylation catalyst include platinum, platinum black, and chloroplatinic acid.

For example, a refractive index of the cured silicone resin may be in a range from 1.35 to 1.55, and more preferably in a range from 1.38 to 1.54. When the refractive index of the silicone resin is within these ranges, the silicone resin has excellent transmissivity and can be suitably used as a resin constituting the wavelength conversion member. Here, the refraction index of the cured silicone resin is measured in accordance with JIS K 7142:2008.

The resin composition contains at least one chelating agent. The chelating agent may be a compound having a plurality of coordination sites and that can perform multidentate coordination with a metal ion, and may be a compound that can perform coordination with at least a manganese ion. The chelating agent may be any selected from the group consisting of a carboxylic acid-based chelating agent, an aminocarboxylic acid-based chelating agent, a phosphonic acid-based chelating agent, and the like. The chelating agent may preferably include at least one selected from the group consisting of an aminocarboxylic acid-based chelating agent and a phosphonic acid-based chelating agent. The chelating agent contained in the resin composition may be one kind alone or a combination of two or more kinds. The chelating agent contained in the resin composition may be in the form of a free acid or in the form of a metal salt containing an alkali metal or the like.

Specific examples of the chelating agent include gluconic acid, ethylenediaminetetraacetic acid (EDTA), nitrilotriacetic acid (NTA), diethylenetriaminepentaacetic acid (DTPA), hydroxyethylethylenediaminetriacetic acid (HEDTA), triethylenetriaminehexaacetic acid (TTHA), 1,3-propanediaminetriacetic acid (PDTA), 1,3-diamino-2-hydroxypropanetetraacetic acid (DPTA-OH), hydroxyethyliminodiacetic acid (HIDA), dihydroxyethylglycine (DHEG), glycoletherdiaminetetraacetic acid (GEDTA), dicarboxymethylglutamic acid (CMGA), ethylenediaminedisuccinic acid (EDDS), hydroxyethylenediaminediphosphonic acid (HEDP), nitrilotrismethylenephosphonic acid (NTMP), phosphonobutanetricarboxylic acid (PBTC), and ethylenediaminetetramethylenephosphonic acid (EDTMP), and at least one selected from the group consisting of these may be contained.

The chelating agent may preferably include at least one selected from the group consisting of ethylenediaminetetraacetic acid (EDTA), diethylenetriaminepentaacetic acid (DTPA), hydroxyethylethylenediaminetriacetic acid (HEDTA), hydroxyethylenediaminediphosphonic acid (HEDP), nitrilotrismethylenephosphonic acid (NTMP), and phosphonobutanetricarboxylic acid (PBTC).

The content of the chelating agent in the resin composition may be, for example, in a range from 0.005 to 0.3, preferably 0.008 or more, 0.01 or more, or 0.012 or more, and preferably 0.1 or less, 0.05 or less, 0.03 or less, or 0.02 or less as a mass ratio relative to the mass of the silicone resin.

The resin composition contains at least one kind of Mn-activated fluoride phosphor (hereinafter, also simply referred to as “fluoride phosphor”). The fluoride phosphor contained in the resin composition may be one kind alone or a combination of two or more kinds.

The fluoride phosphor may have a composition containing an element M including at least one selected from the group consisting of Group 4 elements, Group 13 elements, and Group 14 elements, and also an alkali metal, Mn, and F. The composition of the fluoride phosphor is such that when the number of moles of the alkali metal is 2, the number of moles of Mn may be greater than 0 and less than 0.2, and may be preferably in a range from 0.01 to 0.12. The composition of the fluoride phosphor is also such that when the number of moles of the alkali metal is 2, the number of moles of the element M may be greater than 0.8 and less than 1, and may be preferably in a range from 0.88 to 0.99. The composition of the fluoride phosphor is also such that when the number of moles of the alkali metal is 2, the number of moles of F may be greater than 5 and less than 7, and may be preferably in a range from 5.9 to 6.1. The composition of the fluoride phosphor can be measured, for example, by inductively coupled plasma (ICP) emission spectroscopy.

The alkali metal in the composition of the fluoride phosphor may include at least one selected from the group consisting of lithium (Li), sodium (Na), potassium (K), rubidium (Rb), and cesium (Cs). The alkali metal may include at least potassium (K), and at least one selected from the group consisting of lithium (Li), sodium (Na), rubidium (Rb), and cesium (Cs). A ratio of the number of moles of potassium (K) to a total number of moles of the alkali metal in the composition may be, for example, 0.90 or greater, and preferably 0.95 or greater, or 0.97 or greater. The upper limit of the ratio of the number of moles of K may be, for example, not greater than 1 or 0.995. In the composition of the fluoride phosphor, some of the alkali metals may be substituted with ammonium ions (NH₄⁺). When some of the alkali metals are substituted with ammonium ions, the ratio of the number of moles of the ammonium ions to the total number of moles of the alkali metal in the composition may be, for example, 0.10 or less, and preferably 0.05 or less, or 0.03 or less. A lower limit of the ratio of the number of moles of ammonium ions may be, for example, greater than 0, and may be preferably 0.005 or greater.

The element M in the composition of the fluoride phosphor includes at least one selected from the group consisting of Group 4 elements, Group 13 elements, and Group 14 elements. Examples of Group 4 elements include titanium (Ti), zirconium (Zr), and hafnium (Hf), and at least one selected from the group consisting of these elements may be included. Examples of Group 13 elements include boron (B), aluminum (Al), gallium (Ga), indium (In), and thallium (Tl), and at least one selected from the group consisting of these elements may be included. Examples of Group 14 elements include carbon (C), silicon (Si), germanium (Ge), and tin (Sn), and at least one selected from the group consisting of these elements may be included. The element M may include at least one of at least the Group 14 elements, may preferably include at least one of at least Si and Ge, and may more preferably include at least Si. In addition, the element M may include at least one of the Group 13 elements and at least one of the Group 14 elements, and preferably at least one of Al, Si, and Ge, and more preferably at least Al and Si.

A first composition, which is one aspect of the composition of the fluoride phosphor, may contain, as the element M, at least one selected from the group consisting of Group 4 elements and Group 14 elements, preferably at least one selected from the group consisting of Group 14 elements, and more preferably at least one of Si and Ge, and even more preferably at least Si. In addition, the first composition of the fluoride phosphor may have a total number of moles of Si, Ge, and Mn in a range from 0.9 to 1.1, preferably in a range from 0.95 to 1.05, or in a range from 0.97 to 1.03, relative to 2 moles of the alkali metal.

The first composition of the fluoride phosphor may be a composition represented by Formula (1).

A¹_{c}[M¹_{1-b}Mn_{b}F_{d}] (1)

In Formula (1), A¹ may include at least one selected from the group consisting of Li, Na, K, Rb, and Cs. M¹ comprises at least Si and/or Ge, and may further comprise at least one element selected from the group consisting of Group 4 elements and Group 14 elements. Mn may be a tetravalent Mn ion. b satisfies 0<b<0.2, c is an absolute value of electric charge of [M²_{1-b}Mn_{b}F_{d}] ion, and d satisfies 5<d<7.

A¹ in Formula (1) includes at least K, and may further include at least one selected from the group consisting of Li, Na, Rb, and Cs. Also, some of the A¹ may be substituted with ammonium ions (NH₄⁺). When some of the A¹ are substituted with ammonium ions, a ratio of a number of moles of the ammonium ions to a total number of moles of A¹ in the composition may be, for example, 0.10 or less, and preferably 0.05 or less or 0.03 or less. A lower limit of the ratio of the number of moles of ammonium ions may be, for example, greater than 0, and may be preferably 0.005 or greater.

In Formula (1), b is preferably in a range from 0.005 to 0.15, from 0.01 to 0.12, or from 0.015 to 0.1. Also, c may be, for example, in a range from 1.8 to 2.2, preferably from 1.9 to 2.1, or from 1.95 to 2.05. Furthermore, d is preferably in a range from 5.5 to 6.5, from 5.9 to 6.1, from 5.92 to 6.05, or from 5.95 to 6.025.

A second composition, which is one aspect of the composition of the fluoride phosphor, may contain, as the element M, at least one element selected from the group consisting of Group 4 elements and Group 14 elements and at least one Group 13 element, and preferably at least one element selected from the group consisting of Group 14 elements and at least one Group 13 element, and more preferably at least Si and Al. In addition, the second composition of the fluoride phosphor may have a total number of moles of Si, Al, and Mn in a range from 0.9 to 1.1, preferably in a range from 0.95 to 1.05, or in a range from 0.97 to 1.03, relative to 2 moles of the alkali metal. Furthermore, the second composition of the fluoride phosphor may have a number of moles of Al greater than 0 and 0.1 or less, and preferably greater than 0 and 0.03 or less, in a range from 0.002 to 0.02, or in a range from 0.003 to 0.015, relative to 2 moles of the alkali metal.

The second composition of the fluoride phosphor may be a composition represented by Formula (2).

A²_{f}[M²₁₋ₑMnₑF_{g}] (2)

In Formula (2), A² includes at least K, and may further include at least one selected from the group consisting of Li, Na, Rb, and Cs. M² comprises at least Si and Al, and may further comprise at least one element selected from the group consisting of Group 4 elements, Group 13 elements, and Group 14 elements. Mn may be a tetravalent Mn ion. e satisfies 0<e<0.2, f is the absolute value of the charge of the [M²₁₋ₑMnₑF_{g}] ion, and g satisfies 5<g<7.

Also, some of the A² in Formula (2) may be substituted with ammonium ions (NH₄⁺). When some of the A² are substituted with ammonium ions, a ratio of a number of moles of the ammonium ions to a total number of moles of A² in the composition may be, for example, 0.10 or less, and preferably 0.05 or less or 0.03 or less. A lower limit of the ratio of the number of moles of ammonium ions may be, for example, greater than 0, and may be preferably 0.005 or greater.

In Formula (2), e is preferably in a range from 0.005 to 0.15, from 0.01 to 0.12, or from 0.015 to 0.1. Also, f may be, for example, in a range from 1.8 to 2.2, preferably from 1.9 to 2.1, or from 1.95 to 2.05. Furthermore, g is preferably in a range from 5.5 to 6.5, in a range from 5.9 to 6.1, from 5.92 to 6.05, or from 5.95 to 6.025.

The fluoride phosphor having the second composition may have irregularities, or the like on the surface of particles. The irregularities may include not only scattered irregularities but also grooves. The state of the particle surface can be evaluated by, for example, measuring the angle of repose of the powder of fluoride phosphor. The angle of repose of the powder of fluoride phosphor having the second composition may be, for example, 70° or lower, and preferably 65° or lower or 60° or lower. A lower limit of the angle of repose is, for example, 30° or higher. The angle of repose is measured by, for example, an injection method.

In perspective of brightness improvement, a volume-based median diameter of the fluoride phosphor may be, for example, in a range from 5 μm to 90 μm, and is preferably in a range from 10 μm to 70 μm or in a range from 15 μm to 50 μm. In perspective of brightness improvement, a particle size distribution of the fluoride phosphor may have a single peak, and preferably have a single peak with a narrow distribution range. Specifically, in a volume-based particle size distribution, when a particle size corresponding to 10% cumulative volume from the small diameter side is D10, and the particle size corresponding to 90% cumulative volume from the small diameter side is D90, the ratio of D90 to D10 (D90/D10) may be 3.0 or less, for example. The volume-based median diameter is a particle size corresponding to a cumulative volume of 50% from the small diameter side in the volume-based particle size distribution, and the volume-based particle size distribution is measured by a laser diffraction particle size distribution measuring device.

The fluoride phosphor is, for example, a phosphor activated by a tetravalent manganese, and the fluoride phosphor may absorb light of a short wavelength range of visible light and emit red light. The light irradiated to the fluoride phosphor may be primarily light in the blue region, and a peak wavelength of the light may be within a wavelength range of, for example, from 380 nm to 485 nm. An emission peak wavelength in an emission spectrum of the fluoride phosphor may be, for example, within a wavelength range from 610 nm to 650 nm. A full width at half maximum in the emission spectrum of the fluoride phosphor may be, for example, 10 nm or less.

The fluoride phosphor can exhibit excellent emission efficiency. An internal quantum efficiency of the fluoride phosphor may be, for example, 88% or more, and preferably 93% or more, or 94% or more. The internal quantum efficiency of the fluoride phosphor is measured by exciting light of 450 nm using, for example, a quantum efficiency measuring device.

The fluoride phosphor can be produced by a known method. Japanese Patent Publication No. 2014-141684 A, Japanese Patent Publication No. 2015-143318 A, Japanese Patent Publication No. 2015-188075 A, and the like can be referenced, for example, for details on the method for manufacturing a fluoride phosphor having the first composition. In addition, Japanese Patent Publication No. 2010-254933 A, Japanese Patent Publication No. 2022-099232 A, and the like can be referenced, for example, for details on the method for manufacturing a fluoride phosphor having the second composition.

A content of the fluoride phosphor in the resin composition may be, for example, in a range from 0.1 to 2 or less, preferably from 0.2 or greater, or 0.3 or greater, and preferably 1.5 or less, or 1 or less, in terms of a mass ratio of the mass of the fluoride phosphor to the mass of the silicone resin.

The content of the chelating agent in the resin composition may be, for example, in a range from 0.0025 to 3, preferably 0.005 or greater, 0.01 or greater, 0.02 or greater, or 0.03 or greater, and preferably 2 or less, 1 or less, 0.5 or less, 0.1 or less, or 0.05 or less, in terms of a mass ratio of the mass of the chelating agent to the mass of the fluoride phosphor.

In addition to the fluoride phosphor, the resin composition may further contain a phosphor other than the fluoride phosphor and a light-emitting material such as a quantum dot. Examples of the phosphor include yttrium-aluminum (gallium-doped) garnet activated with cerium, nitrogen-containing calcium aluminosilicate (strontium) activated with europium, and a β-sialon phosphor. Specific examples of the phosphor include: an oxynitride based phosphor such as an yttrium aluminum garnet based phosphor (for example, (Y,Gd)₃(Al,Ga)₅O₁₂:Ce), a lutetium aluminum garnet based phosphor (for example, Lu₃(Al,Ga)₅O₁₂:Ce), a terbium aluminum garnet based phosphor (for example, Tb₃(Al,Ga)₅O₁₂:Ce), a CCA based phosphor (for example, Ca₁₀(PO₄)₆C₁₂:Eu), an SAE based phosphor (for example, Sr₄Al₁₄O₂₅:Eu), a chlorosilicate based phosphor (for example, Ca₈MgSi₄O₁₆C₁₂:Eu), silicate-based phosphors (for example, (Ba,Sr,Ca,Mg)₂SiO₄:Eu), a β-SiAlON based phosphor (for example, (Si,Al)₃(O,N)₄:Eu), or an α-SiAlON based phosphor (for example, Ca(Si,Al)₁₂(O,N)₁₆:Eu); a nitride based phosphor such as an LSN based phosphor (for example, (La,Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or SCASN phosphors (for example, (Sr,Ca)AlSiN₃:Eu); and a fluoride-based phosphor such as MGF-based phosphors (for example, 3.5MgO·0.5MgF₂/GeO₂:Mn). Examples of the quantum dot include a quantum dot having a perovskite structure (for example, (Cs,FA,MA) (Pb,Sn) (F,Cl,Br,I)₃, where FA represents formamidinium and MA represents methylammonium), a II-VI quantum dot (for example, CdSe), a III-V quantum dot (for example, InP), and a quantum dot having a chalcopyrite structure (for example, (Ag,Cu) (In,Ga) (S,Se)₂).

The resin composition may further contain inorganic particles. The inorganic particles may be, for example, a light-diffusing material. Examples of the material of the inorganic particles include silicon oxide, titanium oxide, zinc oxide, zirconium oxide, and aluminum oxide. A median diameter of the inorganic particles may be, for example, in a range from 5 nm to 5 μm. A content of the inorganic particles in the resin composition may be, for example, in a range from 0.002 to 0.02 in terms of a mass ratio of the mass of the inorganic particles to the mass of the silicone resin. The resin composition may contain one kind of inorganic particles alone, or may contain two or more kinds in combination.

The resin composition can be prepared by mixing the silicone resin, the Mn-activated fluoride phosphor, and the chelating agent. The mixing method can be appropriately selected from commonly used mixing methods. Specific examples of the mixing method include a method using a known mixer such as a planetary centrifugal mixer, a three roll mill, a rotary mixer, or a twin-screw mixer.

Light-Emitting Device

The light-emitting device is provided with, for example, a substrate, a light-emitting element disposed on the substrate, and a wavelength conversion member that converts the light-emitting element. The wavelength conversion member may include a cured product of a silicone resin, a Mn-activated fluoride phosphor, and a chelating agent. Since the wavelength conversion member covering the light-emitting element contains the Mn-activated fluoride phosphor and the chelating agent, a decrease in the luminous flux of the light-emitting device due to a change with time of the Mn-activated fluoride phosphor is reduced.

The wavelength conversion member provided in the light-emitting device may be a cured product of the above-described resin composition. Therefore, for the details of the configuration of the wavelength conversion member, the configuration of the resin composition described above can be referred to.

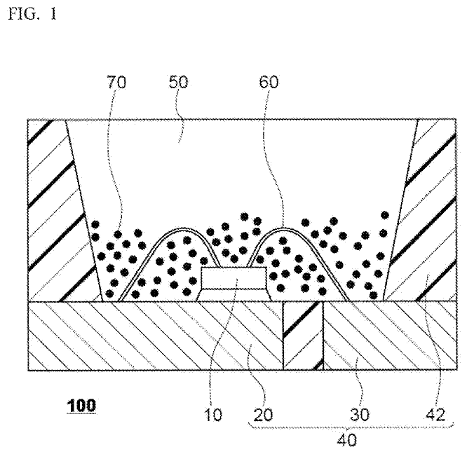

An example of the light-emitting device will be described on the basis of the drawings. FIG. 1 is a schematic cross-sectional view illustrating an example of a light-emitting device according to the present embodiment. This light-emitting device is an example of a surface-mounted light-emitting device. A light-emitting device 100 includes a light-emitting element 10 that emits light having an emission peak wavelength on the short-wavelength side of visible light (for example, in a range from 380 nm to 485 nm), and a molded body 40 on which the light-emitting element 10 is mounted. The molded body 40 has a first lead 20 and a second lead 30, and is integrally molded with a thermoplastic resin or a thermosetting resin. The molded body 40 forms a recessed portion including a bottom surface and a lateral surface corresponding to the substrate, and the light-emitting element 10 is mounted on the bottom surface of the recessed portion. The light-emitting element 10 includes a pair of positive and negative electrodes, and the pair of the positive and negative electrodes are electrically connected to the first lead 20 and the second lead 30 via wires 60. The light-emitting element 10 is covered with the wavelength conversion member 50. The wavelength conversion member 50 contains a phosphor 70 containing a fluoride phosphor that wavelength-converts light from the light-emitting element 10, a cured product of a silicone resin, and a chelating agent. In addition to the fluoride phosphor, the phosphor 70 may contain a light-emitting material that emits light having an emission peak wavelength in a wavelength range different from that of the fluoride phosphor by excitation light from the light-emitting element 10.

The light-emitting element may emit light having an emission peak wavelength in a wavelength range from 380 nm to 485 nm, which is a short wavelength range of visible light. The light-emitting element may be an excitation light source that excites a fluoride phosphor. The light-emitting element preferably has an emission peak wavelength within a range from 380 nm to 480 nm, more preferably has an emission peak wavelength within a range from 410 nm to 480 nm, and even more preferably has an emission peak wavelength within a range from 430 nm to 480 nm. A semiconductor light-emitting element is preferably used as the light-emitting element of the excitation light source. By using a semiconductor light-emitting element as an excitation light source, a stable light-emitting device that exhibits high efficiency and high output linearity with respect to an input and that is strong against mechanical impact can be obtained. As the semiconductor light-emitting element, for example, a semiconductor light-emitting element that uses a nitride-based semiconductor can be used. The full width at half maximum of the emission peak in the emission spectrum of the light-emitting element may be 30 nm or less, for example.

The invention related to the present disclosure may encompass the following aspects.

[1] A resin composition including:
a silicone resin;
a Mn-activated fluoride phosphor; and
a chelating agent.

[2] The resin composition according to [1], in which the chelating agent includes at least one selected from the group consisting of an aminocarboxylic acid-based chelating agent and a phosphonic acid-based chelating agent.

[3] The resin composition according to [1], in which the chelating agent includes at least one selected from the group consisting of gluconic acid, ethylenediaminetetraacetic acid (EDTA), nitrilotriacetic acid (NTA), diethylenetriaminepentaacetic acid (DTPA), hydroxyethylethylenediaminetriacetic acid (HEDTA), triethylenetriaminehexaacetic acid (TTHA), 1,3-propanediaminetriacetic acid (PDTA), 1,3-diamino-2-hydroxypropanetetraacetic acid (DPTA-OH), hydroxyethyliminodiacetic acid (HIDA), dihydroxyethylglycine (DHEG), glycoletherdiaminetetraacetic acid (GEDTA), dicarboxymethylglutamic acid (CMGA), ethylenediaminedisuccinic acid (EDDS), hydroxyethylenediaminediphosphonic acid (HEDP), nitrilotrismethylenephosphonic acid (NTMP), phosphonobutanetricarboxylic acid (PBTC), and ethylenediaminetetramethylenephosphonic acid (EDTMP).

[4] The resin composition according to any one of [1] to [3], in which the fluoride phosphor has a composition containing an element M including at least one selected from the group consisting of Group 4 elements, Group 13 elements, and Group 14 elements; an alkali metal; Mn; and F, and in which when a number of moles of the alkali metal is 2, a number of moles of Mn is greater than 0 and less than 0.2, a number of moles of the element M is greater than 0.8 and less than 1, and a number of moles of F is greater than 5 and less than 7.

[5] The resin composition according to any one of [1] to [4], in which a mass ratio of a mass of the chelating agent to a mass of the silicone resin is in a range from 0.005 to 0.3.

[6] The resin composition according to any one of [1] to [5], in which a mass ratio of a mass of the chelating agent to a mass of the fluoride phosphor is in a range from 0.0025 to 3.

[7] A light-emitting device including:
a substrate;
a light-emitting element disposed on the substrate; and
a wavelength conversion member covering the light-emitting element, wherein the wavelength conversion member includes a cured product of a silicone resin, a Mn-activated fluoride phosphor, and a chelating agent.

[8] The light-emitting device according to [7], in which the chelating agent includes at least one selected from the group consisting of an aminocarboxylic acid-based chelating agent and a phosphonic acid-based chelating agent.

[9] The light-emitting device according to [7], in which the chelating agent includes at least one kind selected from the group consisting of gluconic acid, ethylenediaminetetraacetic acid (EDTA), nitrilotriacetic acid (NTA), diethylenetriaminepentaacetic acid (DTPA), hydroxyethylethylenediaminetriacetic acid (HEDTA), triethylenetriaminehexaacetic acid (TTHA), 1,3-propanediaminetriacetic acid (PDTA), 1,3-diamino-2-hydroxypropanetetraacetic acid (DPTA-OH), hydroxyethyliminodiacetic acid (HIDA), dihydroxyethylglycine (DHEG), glycoletherdiaminetetraacetic acid (GEDTA), dicarboxymethylglutamic acid (CMGA), ethylenediaminedisuccinic acid (EDDS), hydroxyethylenediaminediphosphonic acid (HEDP), nitrilotrismethylenephosphonic acid (NTMP), phosphonobutanetricarboxylic acid (PBTC), and ethylenediaminetetramethylenephosphonic acid (EDTMP).

[10] The light-emitting device according to any one of [7] to [9], in which the fluoride phosphor has a composition containing an element M including at least one selected from the group consisting of Group 4 elements, Group 13 elements, and Group 14 elements; an alkali metal; Mn; and F, and in which when a number of moles of the alkali metal is 2, a number of moles of Mn is greater than 0 and less than 0.2, a number of moles of the element M is greater than 0.8 and less than 1, and a number of moles of F is greater than 5 and less than 7.

[11] The light-emitting device according to any one of [7] to [10], in which in the wavelength conversion member, a mass ratio of a mass of the chelating agent to a mass of a cured product of the silicone resin is in a range from 0.005 to 0.3.

[12] The light-emitting device according to any one of [7] to [11], in which in the wavelength conversion member, a mass ratio of a mass of the chelating agent to a mass of the fluoride phosphor is in a range from 0.0025 to 3.

### EXAMPLES

The present invention will be described in detail below by using examples, but the present invention is not limited to these examples.

### Example 1

1.6 parts by mass of sodium hydroxyethylenediaminediphosphonate (HEDP) (manufactured by Chelest Corporation) as a chelating agent and 50 parts by mass of a fluoride phosphor (KSF) having a theoretical composition represented by K₂SiF₆:Mn were added to 100 parts by mass of an addition-curable silicone resin (OE7660, manufactured by Dow Corning Toray Co., Ltd.), and the mixture was stirred at room temperature (25° C.) to produce a resin composition. The resin composition was filled in a recess of an LED package (NFSW757G V3, manufactured by Nichia Corporation) on which light-emitting elements were mounted, and the resin composition was cured by heat treatment at 150° C. for 4 hours to produce a light-emitting device 1 of Example 1.

### Example 2

A light-emitting device 2 of Example 2 was produced in the same manner as in Example 1 except that the chelating agent was changed to sodium nitrilotrismethylenephosphonate (NTMP) (manufactured by Chelest Corporation).

### Example 3

A light-emitting device 3 of Example 3 was produced in the same manner as in Example 1 except that the chelating agent was changed to sodium diethylenetriaminepentaacetic acid (DTPA) (manufactured by Chelest Corporation).

### Example 4

A light-emitting device 4 of Example 4 was produced in the same manner as in Example 1 except that the chelating agent was changed to sodium ethylenediaminetetraacetic acid (EDTA) (manufactured by Chelest Corporation).

### Example 5

A light-emitting device 5 of Example 5 was produced in the same manner as in Example 1 except that the chelating agent was changed to sodium phosphonobutanetricarboxylic acid (PBTC) (manufactured by Chelest Corporation).

### Example 6

A light-emitting device 6 of Example 6 was produced in the same manner as in Example 1 except that the chelating agent was changed to phosphonobutanetricarboxylic acid (PBTC) (manufactured by Chelest Corporation).

### Comparative Example 1

Alight-emitting device Cl of Comparative Example 1 was produced in the same manner as in Example 1 except that the chelating agent was not added.

Reliability Evaluation

Each of the light-emitting devices produced as described above was lit at a current value of 65 mA before the storage test, and the luminous flux was measured. Next, after a storage test for 858 hours in an atmosphere of 85° C. and 85% RH, the device was lit under the same conditions and luminous flux was measured. The luminous flux after the storage test was divided by the luminous flux before the storage test to calculate a luminous flux maintenance factor (%). The results are shown in Table 1.

TABLE 1

| | | Luminous flux |
|---|---|---|
| | Chelating agent | maintenance ratio (%) |
| Example 1 | HEDP-Na | 96.5 |
| Example 2 | NTMP-Na | 95.2 |
| Example 3 | DTPA-Na | 93.7 |
| Example 4 | EDTA-Na | 93.9 |
| Example 5 | PBTC-Na | 95.1 |
| Example 6 | PBTC | 93.7 |
| Comparative Example 1 | — | 91.4 |

As shown in Table 1, the reliability of the light-emitting device is improved by forming the wavelength conversion member using the resin composition containing the chelating agent in addition to the silicone resin.

1. A resin composition comprising:
a silicone resin;
a Mn-activated fluoride phosphor; and
a chelating agent.

2. The resin composition according to claim 1, wherein the chelating agent includes at least one selected from the group consisting of an aminocarboxylic-acid-based chelating agent and a phosphonic-acid-based chelating agent.

3. The resin composition according to claim 1, wherein the chelating agent includes at least one selected from the group consisting of gluconic acid, ethylenediaminetetraacetic acid (EDTA), nitrilotriacetic acid (NTA), diethylenetriaminepentaacetic acid (DTPA), hydroxyethylethylenediaminetriacetic acid (HEDTA), triethylenetriaminehexaacetic acid (TTHA), 1,3-propanediaminetriacetic acid (PDTA), 1,3-diamino-2-hydroxypropanetetraacetic acid (DPTA-OH), hydroxyethyliminodiacetic acid (HIDA), dihydroxyethylglycine (DHEG), glycoletherdiaminetetraacetic acid (GEDTA), dicarboxymethylglutamic acid (CMGA), ethylenediaminedisuccinic acid (EDDS), hydroxyethylenediaminediphosphonic acid (HEDP), nitrilotrismethylenephosphonic acid (NTMP), phosphonobutanetricarboxylic acid (PBTC), and ethylenediaminetetramethylenephosphonic acid (EDTMP).

4. The resin composition according to claim 1, wherein the fluoride phosphor has a composition containing an alkali metal; Mn; F; and an element M including at least one selected from the group consisting of Group 4 elements, Group 13 elements, and Group 14 element, and in which when a number of moles of the alkali metal is 2, a number of moles of Mn is greater than 0 and less than 0.2, a number of moles of the element M is greater than 0.8 and less than 1, and a number of moles of F is greater than 5 and less than 7.

5. The resin composition according to claim 1,
wherein in the resin composition, a mass ratio of a mass of the chelating agent to a mass of the silicone resin is in a range from 0.005 to 0.3.

6. The resin composition according to claim 1,
wherein in the resin composition, a mass ratio of a mass of the chelating agent to a mass of the fluoride phosphor is in a range from 0.0025 to 3.

7. A light-emitting device comprising:
a substrate;
a light-emitting element disposed on the substrate; and
a wavelength conversion member covering the light-emitting element,
wherein the wavelength conversion member includes a cured product of a silicone resin, a Mn-activated fluoride phosphor, and a chelating agent.

8. The light-emitting device according to claim 7, wherein the chelating agent includes at least one selected from the group consisting of an aminocarboxylic acid-based chelating agent and a phosphonic acid-based chelating agent.

9. The light-emitting device according to claim 7, wherein the chelating agent includes at least one selected from the group consisting of gluconic acid, ethylenediaminetetraacetic acid (EDTA), nitrilotriacetic acid (NTA), diethylenetriaminepentaacetic acid (DTPA), hydroxyethylethylenediaminetriacetic acid (HEDTA), triethylenetriaminehexaacetic acid (TTHA), 1,3-propanediaminetriacetic acid (PDTA), 1,3-diamino-2-hydroxypropanetetraacetic acid (DPTA-OH), hydroxyethyliminodiacetic acid (HIDA), dihydroxyethylglycine (DHEG), glycoletherdiaminetetraacetic acid (GEDTA), dicarboxymethylglutamic acid (CMGA), ethylenediaminedisuccinic acid (EDDS), hydroxyethylenediaminediphosphonic acid (HEDP), nitrilotrismethylenephosphonic acid (NTMP), phosphonobutanetricarboxylic acid (PBTC), and ethylenediaminetetramethylenephosphonic acid (EDTMP).

10. The light-emitting device according to claim 7, wherein the fluoride phosphor has a composition containing an alkali metal; Mn; F; and an element M including at least one selected from the group consisting of Group 4 elements, Group 13 elements, and Group 14 element, and in which when a number of moles of the alkali metal is 2, a number of moles of Mn is greater than 0 and less than 0.2, a number of moles of the element M is greater than 0.8 and less than 1, and a number of moles of F is greater than 5 and less than 7.

11. The light-emitting device according to claim 7, wherein in the wavelength conversion member, a mass ratio of a mass of the chelating agent to a mass of a cured product of the silicone resin is in a range from 0.005 to 0.3.

12. The light-emitting device according to claim 7, wherein in the wavelength conversion member, a mass ratio of a mass of the chelating agent to a mass of the fluoride phosphor is in a range from 0.0025 to 3.
